(19) United States
(12) Patent Application Publication
(10) Pub. No.: US 2026/0362947 A1
(43) Pub. Date: Nov. 12, 2026

(54) Display Module and Display Device

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Yi Zhang, Beijing (CN); Peng Yang, Beijing (CN); Danyang Bi, Beijing (CN); Xiaodong Hao, Beijing (CN); Dianjie Hou, Beijing (CN); Dan Liu, Beijing (CN); Mingqiang Wang, Beijing (CN)

(21) Appl. No.: 19/123,415

(22) PCT Filed: Nov. 25, 2024
(86) PCT No.: PCT/CN2024/134232

§ 371 Date: Apr. 23, 2025

(30) Foreign Application Priority Data
Dec. 20, 2023 (CN) 202311766983.5

(51) Int. Cl. H10K 59/80; H10K 59/40

(52) U.S. Cl. CPC H10K 59/873; H10K 59/40

(57) ABSTRACT

A display module includes a touch function layer, a first flexible printed circuit and a first supporting layer. The touch function layer has a touch surface and a non-touch surface that are oppositely disposed, and includes a first bonding portion; the first bonding portion is located on the non-touch surface. The first flexible printed circuit includes a second bonding portion, a main body portion, and a bending portion disposed between the second bonding portion and the main body portion; part of the second bonding portion is bonded to the first bonding portion, and the bending portion is bent toward the non-touch surface, so that the main body portion is bent onto the non-touch surface. The first supporting layer is disposed on a side of the first flexible printed circuit away from the touch function layer, and the first supporting layer includes a first supporting portion and a second supporting portion that are connected to each other, the first supporting portion covers the second bonding portion and extends to the bending portion; in a first direction, at least part of the second supporting portion is located on a side of the first supporting portion away from the touch function layer, and a bending stiffness of the second supporting portion is less than a bending stiffness of the first supporting portion.

This application claims priority to Chinese Patent Application No. 202311766983.5, filed on Dec. 20, 2023, which is incorporated herein by reference in its entirety.

### TECHNICAL FIELD

The present disclosure relates to the field of display technologies, and in particular, to a display module and a display device.

### BACKGROUND

With the development of display technologies, display devices (e.g., mobile phones, notebook computers, or tablet computers) are increasingly used in people's lives. Organic light-emitting diode (OLED) display devices have received widespread attention due to their advantages of active light emission, wide viewing angle, high contrast, fast response speed, low power consumption, ultra-thin, etc.

### SUMMARY

In an aspect, a display module is provided. The display module includes a touch function layer, a first flexible printed circuit and a first supporting layer. The touch function layer has a touch surface and a non-touch surface that are oppositely disposed; the touch function layer includes a first bonding portion, and the first bonding portion is located on the non-touch surface. The first flexible printed circuit includes a second bonding portion, a main body portion, and a bending portion disposed between the second bonding portion and the main body portion; the second bonding portion is bonded to the first bonding portion, and the bending portion is bent toward the non-touch surface, so that the main body portion is bent onto the non-touch surface. The first supporting layer is disposed on a side of the first flexible printed circuit away from the touch function layer; the first supporting layer includes a first supporting portion and a second supporting portion that are connected to each other, the first supporting portion covers the second bonding portion and extends to the bending portion; in a first direction, at least part of the second supporting portion is located on a side of the first supporting portion away from the touch function layer, and a bending stiffness of the second supporting portion is less than a bending stiffness of the first supporting portion.

In some embodiments, the second supporting portion includes a plurality of supporting strips, the plurality of supporting strips are arranged at intervals in a second direction; the second direction intersects the first direction and is parallel to the touch function layer.

In some embodiments, the second supporting portion includes two supporting strips, and end surfaces of the two supporting strips that are away from each other are flush with an end surface of the first flexible printed circuit.

In some embodiments, the second supporting portion includes one supporting strip; in a second direction, a maximum dimension of the supporting bar is less than a minimum dimension of the first supporting portion; the second direction intersects the first direction and is parallel to the touch function layer.

In some embodiments, the second supporting portion is symmetrical about a first axis; the first axis extends in the first direction and passes through a center of the first flexible printed circuit.

In some embodiments, in the second direction, a ratio of a dimension of the second supporting portion to a dimension of the first flexible printed circuit is in a range of 0.1 to 0.2, inclusive.

In some embodiments, the second supporting portion has a plurality of via holes; at least part of orthogonal projections of the plurality of via holes on the first flexible printed circuit is located within the bending portion.

In some embodiments, the plurality of via holes are symmetrical about a first axis; the first axis extends in the first direction and passes through a center of the first flexible printed circuit.

In some embodiments, a shape of an orthogonal projection of a via hole on the first flexible printed circuit includes a long strip, and the via hole extends in a second direction; the second direction intersects the first direction and is parallel to the touch function layer.

In some embodiments, the first supporting portion and the second supporting portion are of a one-piece structure.

In some embodiments, an elastic modulus of a material of the second supporting portion is less than an elastic modulus of a material of the first supporting portion.

In some embodiments, in the first direction, the second supporting portion includes a first sub-portion and a second sub-portion, the first sub-portion is located between the first supporting portion and the second sub-portion, and an elastic modulus of a material of the second sub-portion is less than an elastic modulus of a material of the material of the first sub-portion.

In some embodiments, the material of the first sub-portion includes ink, and the material of the second sub-portion includes foam.

In some embodiments, the material of the first supporting portion includes polyimide, and the material of the second supporting portion includes at least one of ink, foam, and adhesive.

In some embodiments, a material of the first supporting portion includes a host material and a doping material; a doping concentration of the doping material included in the second supporting portion is different from a doping concentration of the doping material included in the first supporting portion.

In some embodiments, in the first direction, the doping concentration of the doping material included in the second supporting portion gradually increases or gradually decreases.

In some embodiments, in the first direction, an orthographic projection of an end surface of the second supporting portion away from the first supporting portion on the first flexible printed circuit is located within the bending portion, and the second supporting portion is partially located on a side of the first supporting portion away from the touch function layer, and partially located on a side of the first supporting portion away from the first flexible printed circuit. In the first direction, a distance between a surface, away from the first flexible printed circuit, of a part of the second supporting portion that is located on the side of the first supporting portion away from the touch function layer and a surface of the first flexible printed circuit 30 proximate to the second supporting portion is reduced.

In some embodiments, in the first direction, a maximum distance between the bending portion and the touch function layer is d1, and a distance between an end surface of the second supporting portion away from the first supporting portion and an end surface of the touch function layer proximate to the bending portion is d2, wherein d1−d2=0.1 mm.

In some embodiments, a bending radius of the first flexible printed circuit is in a range of 0.3 mm to 0.5 mm, inclusive.

In another aspect, a display device is provided. The display device includes the display module according to any of the embodiments described above.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a diagram showing a structure of a display device, in accordance with some embodiments;

FIG. 2 is a sectional view taken along the section line A-A in FIG. 1;

FIG. 3 is a diagram showing a structure in which a second supporting portion is located in a bending portion, in accordance with some embodiments;

FIG. 4 is a diagram showing a structure in which a second supporting portion extends into a main body portion, in accordance with some embodiments;

FIG. 5 is a front view of a first flexible printed circuit, in accordance with some embodiments;

FIG. 6 is a sectional view taken along the section line H-H in FIG. 5;

FIG. 7 is a rear view of a first flexible printed circuit, in accordance with some embodiments;

FIG. 8 is a diagram showing a structure in which a second supporting portion includes two supporting strips, in accordance with some embodiments;

FIG. 9 is a diagram showing a structure in which a second supporting portion includes one supporting strip, in accordance with some embodiments;

FIG. 10 is a diagram showing a structure in which a dimension of a second supporting portion is gradually reduced in a first direction, in accordance with some embodiments;

FIG. 11 is a diagram showing a structure in which a second supporting portion includes a plurality of via holes, in accordance with some embodiments;

FIG. 12 is a diagram showing a structure in which a number of via holes is gradually reduced in a first direction, in accordance with some embodiments;

FIG. 13 is a diagram showing a structure in which a second supporting portion includes a first sub-portion and a second sub-portion, in accordance with some embodiments;

FIG. 14 is a sectional view taken along the section line B-B in FIG. 13;

FIG. 15 is a diagram showing a structure in which a doping concentration of a doping material of a second supporting portion is greater than a doping concentration of a doping material of a first supporting portion, in accordance with some embodiments;

FIG. 16 is a sectional view taken along the section line C-C in FIG. 15;

FIG. 17 is a diagram showing a structure in which a doping concentration of a doping material of a second supporting portion is less than a doping concentration of a doping material of a first supporting portion, in accordance with some embodiments;

FIG. 18 is a sectional view taken along the section line D-D in FIG. 17;

FIG. 19 is a diagram showing another structure in which a second supporting portion is located in a bending portion, in accordance with some embodiments;

FIG. 20 is a sectional view taken along the section line G-G in FIG. 19; and

FIG. 21 is diagram showing a structure of a first flexible printed circuit, in accordance with some embodiments.

### DETAILED DESCRIPTION

The technical solutions in some embodiments of the present disclosure will be described clearly and completely below with reference to the accompanying drawings; obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled”, “connected”, and derivatives thereof may be used. For example, the term “connected” may be used in the description of some embodiments to indicate that two or more components are in direct physical or electrical contact with each other. For another example, the term “coupled” may be used in the description of some embodiments to indicate that two or more elements are in direct physical or electrical contact. However, the term “coupled” or “communicatively coupled” may also mean that two or more elements are not in direct contact with each other, but still cooperate or interact with each other. The embodiments disclosed herein are not necessarily limited to the contents herein.

The phrase “at least one of A, B and C” has a same meaning as the phrase “at least one of A, B or C”, and both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed as “when” or “in a case where” or “in response to determining that” or “in response to detecting”, depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”.

The use of the phase “applicable to” or “configured to” herein means an open and inclusive language, which does not exclude devices that are applicable to or configured to perform additional tasks or steps.

Additionally, the use of the phase “based on” is meant to be open and inclusive, since a process, step, calculation or other action that is “based on” one or more of the stated conditions or values may, in practice, be based on additional conditions or value beyond those stated.

The term such as “about”, “substantially”, or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; the term “equal” includes absolute equality and approximate equality, and an acceptable range of deviation of the approximate equality may be that, for example, a difference between the two that are equal is less than or equal to 5% of either of the two.

It should be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

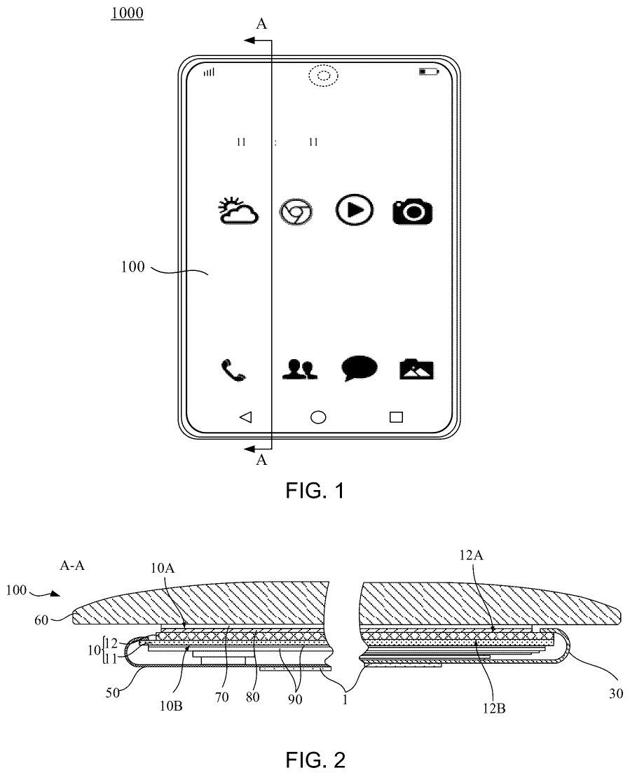

Embodiments of the present disclosure provide a display device 1000, as shown in FIG. 1, the display device 1000 may be any product or component with a display function, such as a notebook computer, a tablet computer, a mobile phone, a personal digital assistant (PDA), a navigator, a wearable apparatus, an augmented reality (AR) apparatus, a virtual reality (VR) apparatus, or car central control screen.

The display device 1000 may be a liquid crystal display (LCD) device, an organic electroluminescent diode display device, a quantum dot light-emitting diode (QLED) display device, a micro light-emitting diode (Micro LED) display device, a mini light-emitting diode (Mini LED) display device, or an active matrix organic light-emitting diode (AMOLED) display device.

It will be noted that, a Micro LED refers to a LED with a size (e.g., a length) less than 50 μm, and a Mini LED refers to a LED with a size (e.g., a length) in a range of 50 μm to 200 μm, inclusive.

The following embodiments of the present disclosure will be schematically described by taking an example in which the display device 1000 is an OLED display device. However, the implementations of the present disclosure are not limited to this, and any other display device 1000 may also be considered, as long as the same technical ideas are applied.

In some embodiments, as shown in FIG. 1, the display device 1000 includes a display module 100. As shown in FIG. 2, the display module 100 includes a display panel 10. The display panel 10 has a display surface 10A and a non-display surface 10B that are oppositely disposed.

It will be noted that, the display surface refers to a surface (an upper surface of the display panel 10 in FIG. 2) of the display panel 10 for displaying pictures, and the non-display surface refers to the other surface (an lower surface of the display panel 10 in FIG. 2) opposite to the display surface.

In some embodiments, as shown in FIG. 2, the display panel 10 includes a display function layer 11 and a touch function layer 12.

As shown in FIG. 2, the display function layer 11 is configured to implement the display function of the display panel 10. For example, the display function layer 11 includes a plurality of sub-pixels, and the plurality of sub-pixels P include first sub-pixels that emit light of a first color, second sub-pixels that emit light of a second color, and third sub-pixels that emit light of a third color. The first color, the second color, and the third color are three primary colors. For example, the first color is red, the second color is blue, and the third color is green, which is not specifically limited in the embodiments of the present disclosure.

As shown in FIG. 2, the touch function layer 12 is located on a side of the display function layer 11, and the touch function layer 12 is configured to implement the touch function of the display panel 10. For example, the touch function layer 12 includes a plurality of touch electrodes, and the plurality of touch electrodes include multiple touch driving electrodes and multiple touch sensing electrodes. The multiple touch sensing electrodes and the multiple touch driving electrodes are insulated from each other and arranged cross each other.

In some embodiments, the display panel further includes a substrate and an encapsulation layer.

The substrate is located on a side of the display function layer 11 away from the touch function layer 12, and the display function layer 11 is disposed on the substrate. The substrate is a rigid substrate. For example, the rigid substrate may be a glass substrate, a polymethyl methacrylate (PMMA) substrate or the like.

The encapsulation layer is disposed between the display function layer 11 and the touch function layer 12, and the touch function layer 12 is disposed on the encapsulation layer. The encapsulation layer 1300 includes rigid encapsulation or flexible film encapsulation. In the case where the encapsulation layer is a rigid encapsulation, the encapsulation layer is a glass encapsulation. In the case where the encapsulation layer is a flexible film encapsulation, the encapsulation layer may include one layer of encapsulation film, or two or more layers of encapsulation films that are stacked. For example, the encapsulation layer includes three encapsulation films that are stacked in sequence.

For example, the substrate is a glass substrate, and the encapsulation layer is a glass encapsulation. The display module further includes an adhesive layer, and the adhesive layer is located between the substrate and the encapsulation layer and is arranged around the plurality of pixels. A material of the adhesive layer is glass glue.

In some embodiments, as shown in FIG. 2, the display module 100 further includes a main flexible printed circuit (MFPC) 1, which is located on the non-display surface B of the display panel 10. The main flexible printed circuit 1 is configured to provide signals for the display function layer 11 and the touch function layer 12.

In some embodiments, as shown in FIG. 2, the display module 100 further includes a first flexible printed circuit 30, and the touch function layer 12 is electrically connected to the main flexible printed circuit through the first flexible printed circuit 30. In this way, the main flexible printed circuit 1 may provide signals for the touch function layer 12 through the first flexible printed circuit 30, and receive feedback signals from multiple touch electrodes, and determine whether the touch electrodes are touched by analyzing the feedback signals, thereby realizing the touch function. In this case, the first flexible printed circuit 30 may be referred to as a touch flexible printed circuit (TFPC).

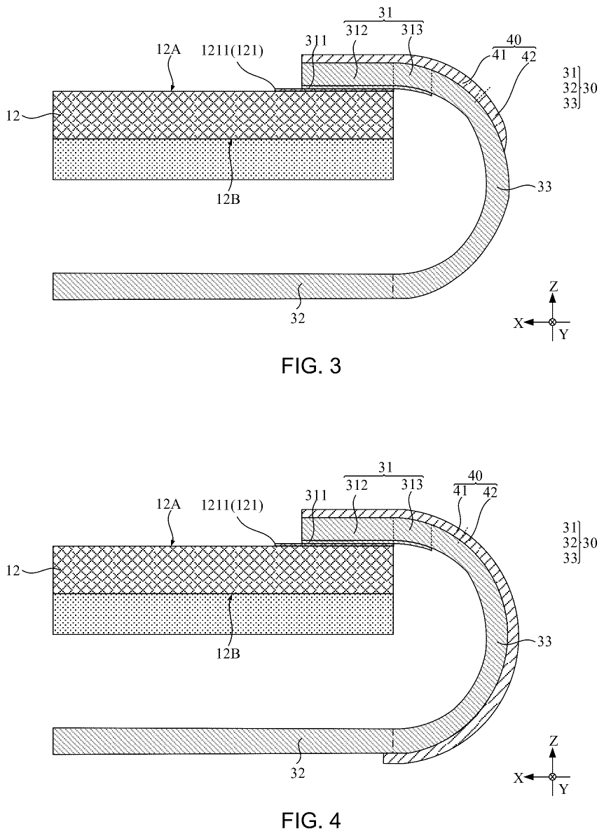

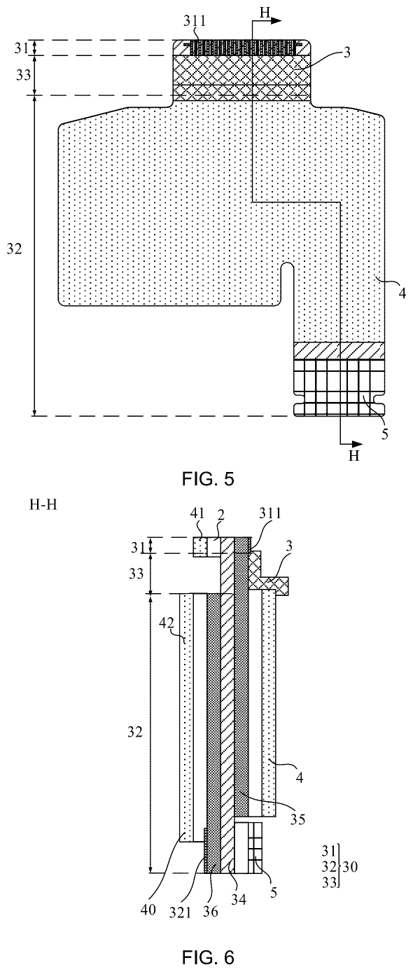

It will be noted that the first flexible printed circuit 30 has two states: an unfolded state and a bent state. The bent state is shown in FIGS. 3 and 4, and the unfolded state is shown in FIGS. 5, 6, 7 and 8. The first flexible printed circuit 30 in the unfolded state in FIG. 8 is substantially in a shape of a rectangle.

As used herein, the description “substantially in a shape of a rectangle” means that in a shape of a rectangle as a whole, but is not limited to a standard rectangle. That is, “rectangle” herein includes not only the shape of a basic rectangle, but also a shape similar to a rectangle. For example, the long and short sides of the rectangle are curved at each intersecting position (i.e., at each corner), i.e., the corners are smooth and the shape is a rounded rectangle. The following description will be made by taking an example in which the first flexible printed circuit 30 in the unfolded state is substantially in a shape of rectangle.

For example, as shown in FIGS. 3 and 4, the touch function layer 12 has a touch surface 12A and a non-touch surface 12B that are oppositely disposed. The touch function layer 12 includes a first bonding portion 121. For example, the first bonding portion 121 includes a plurality of first bonding pins 1211. The touch surface 12A refers to a surface (the upper surface of the touch function layer 12 in FIG. 2) of the touch function layer 12 that realizes the touch function, and the non-touch surface 12B refers to the other surface (the lower surface of the touch function layer 12 in FIG. 2) opposite to the touch surface 12A.

As shown in FIGS. 5 and 6, the first flexible printed circuit 30 has a second bonding portion 31, a main body portion 32, and a bending portion 33 disposed between the second bonding portion 31 and the main body portion 32. For example, the second bonding portion 31 includes a plurality of second bonding pins 311.

As shown in FIGS. 3 and 4, the second bonding portion 31 is bonded to the first bonding portion 121 by a bonding process, so that the touch function layer 12 and the first flexible printed circuit 30 are bonded.

As shown in FIGS. 3 and 4, through the bending process, the bending portion 33 is bent along the bending axis extending in the second direction Y toward the non-touch surface 12B, so that the main body portion 32 is bent onto the non-touch surface 12B.

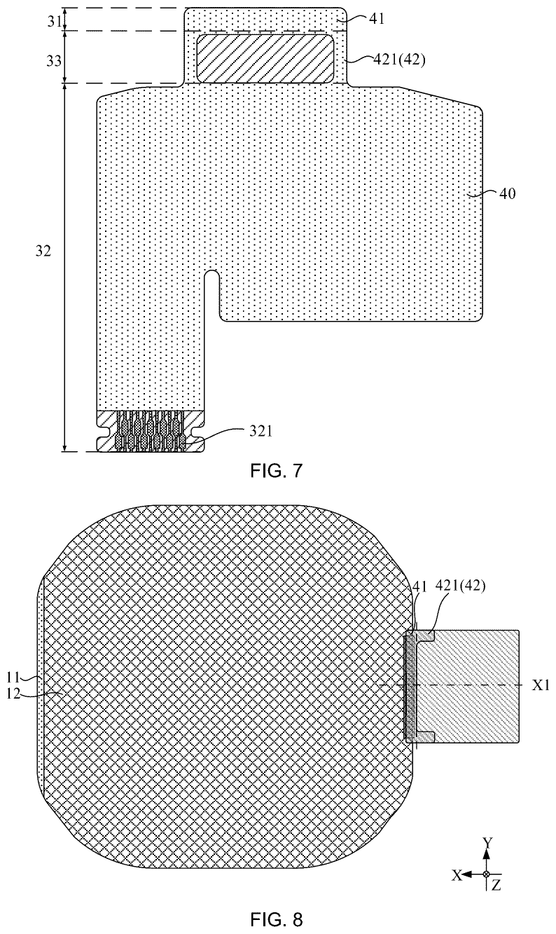

In some embodiments, as shown in FIGS. 6 and 7, the main body portion 32 includes a plurality of plug pins 321, and the plurality of plug pins 321 are connected to the main flexible printed circuit 1, so that the first flexible printed circuit 30 is connected to the main flexible printed circuit, and the main flexible printed circuit 1 is connected to the touch function layer 12. The bending axis is not an actual structure existing in the display panel 10, but is only a concept proposed to illustrate the bending process of the first flexible printed circuit 30.

It will be noted that, in the bonding process, generally, only a part of the second bonding portion 31 is bonded to the first bonding portion 121. Therefore, during the bending process, the bending portion 33 will drive the unbonded second bonding portion 31 to bend toward the non-touch surface 12B. That is, as shown in FIGS. 3 and 4, the second bonding portion 31 includes a first bonding sub-portion 312 and a second bonding sub-portion 313 that are connected, the first bonding sub-portion 312 is bonded to the first bonding portion 121, the second bonding sub-portion 313 is located between the first bonding sub-portion 312 and the bending portion, and the second bonding sub-portion 313 is bent toward the non-touch surface 12B.

In some embodiments, as shown in FIGS. 3, 4, 6 and 7, the display module 100 further includes a first supporting layer 40. As shown in FIGS. 3 and 4, the first supporting layer 40 is arranged on a side of the first flexible printed circuit 30 away from the touch function layer 12, and the first supporting layer 40 covers the second bonding portion 31. In this way, the first supporting layer 40 may provide support for the second bonding portion 31, which may ameliorate the deformation problem of the second bonding portion 31, and is beneficial to improving the reliability of the bonding between the second bonding portion 31 and the first bonding portion 121.

Based on this, as shown in FIG. 6, the display module 100 further includes a second adhesive layer 2. The second adhesive layer 2 is used to bond the first flexible printed circuit 30 and the first supporting layer 40.

In some embodiments, as shown in FIG. 6, the first flexible printed circuit 30 includes a base layer 34, a first conductive layer 35 and a second conductive layer 36. The first conductive layer 35 is located on a side of the base layer 34, and the first conductive layer 35 includes second bonding pins 311. The second conductive layer 36 is located on a side of the base layer 34 away from the first conductive layer 35, and the second conductive layer 36 includes a plurality of plug pins 321.

In some embodiments, as shown in FIG. 6, the display module 100 further includes a flattening layer 3, and the flattening layer 3 is disposed on a side of the first conductive layer 35 away from the second conductive layer 36; the flattening layer 3 covers a part of the second bonding pins 311 to improve the flatness of the second bonding pins 311, thereby improving the stability and reliability of the connection between the second bonding portion 31 and the first bonding portion 121. For example, a material of the flattening layer 3 may be green ink.

In some embodiments, as shown in FIG. 6, the display module 100 further includes a second supporting layer 4. The second supporting layer 4 is located on a side of the first conductive layer 35 away from the second conductive layer 36 and is included in the main body portion 32. In this way, the second supporting layer 4 may provide support for the main body portion 32, thereby ameliorating the problem of deformation of the main body portion 32.

In some embodiments, as shown in FIG. 6, the display module 100 further includes a third supporting layer 5. The third supporting layer 5 is located on a side of the first conductive layer 35 away from the second conductive layer 36, is included in the main body portion 32, and covers the plurality of plug pins 321. With such an arrangement, the third supporting layer 5 may provide support for the plurality of plug pins 321, which may ameliorate the problem of deformation of the plurality of plug pins 321, and is beneficial to improving the reliability of the connection between the plurality of plug pins 321 and the main flexible printed circuit 1.

In some related technologies, the first supporting layer extends to the bending portion. The total bending stiffness of a part of the bending portion covered by the first supporting layer and the first supporting layer as a whole are a first bending stiffness, the first bending stiffness is relatively great, and the bending resistance is strong; the bending stiffness of a part of the bending portion not covered by the first supporting layer is a second bending stiffness, the bending stiffness is relatively small, and the bending resistance is small, resulting in a large first bending stiffness difference (the difference between the first bending stiffness and the second bending stiffness). Near the end surface of the first supporting layer away from the touch function layer, the bending shape of the first flexible printed circuit is relatively sharp, resulting in a dead bend and too small bending radius, which in turn causes the wirings of the first flexible printed circuit to break.

In some other related technologies, the first supporting layer extends to the main body portion, the bending stiffness of the first supporting layer is too large, and the bending resistance is too large, which will increase the difficulty of bending the first flexible printed circuit, resulting in a large elastic recovery force of the first flexible printed circuit after bending, which will cause the first bonding portion and the second bonding portion to separate.

In order to solve the above problems, as shown in FIGS. 3 and 4, the first supporting layer 40 provided by the embodiments of the present disclosure includes a first supporting portion 41 and a second supporting portion 42 that are connected to each other.

The first supporting portion 41 covers the second bonding portion 31 and extends to the bending portion 33. Arranged in this way, the first supporting portion 41 may provide support for the second bonding portion 31, which may ameliorate the deformation problem of the second bonding portion 31, and is beneficial to improving the reliability of bonding between the second bonding portion 31 and the first bonding portion 121.

As shown in FIG. 3, in a first direction X (the first direction X is parallel to the horizontal direction in FIG. 3), at least part of the second supporting portion 42 is located on a side of the first supporting portion 41 away from the touch function layer 12. The bending rigidity of the second supporting portion 42 is less than the bending rigidity of the first supporting portion 41. Bending stiffness refers to the ability of an object to resist bending deformation.

As shown in FIG. 3, in a case where an orthographic projection of the second supporting portion 42 on the first flexible printed circuit 30 is located within the bending portion 33, a total bending stiffness of the part of the bending portion 33 covered by the first supporting portion 41 and the first supporting portion 41 as a whole is a third bending stiffness, a total bending stiffness of a part of the bending portion 33 covered by the second supporting portion 42 and the second supporting portion 42 as a whole is a fourth bending stiffness, a bending stiffness of a part of the bending portion 33 not covered by the first supporting layer 40 is a fifth bending stiffness, and a difference between the fourth bending stiffness and the fifth bending stiffness is a second bending stiffness difference.

The third bending stiffness is substantially equal to the first bending stiffness, the fifth bending stiffness is substantially equal to the second bending stiffness, and the bending stiffness of the second supporting portion 42 is less than the bending stiffness of the first supporting portion 41. In this case, the fourth bending stiffness is less than the third bending stiffness, that is, the fourth bending stiffness is less than the first bending stiffness, so that the second bending stiffness difference is less than the first bending stiffness difference, and then near the end surface of the first supporting layer 40 away from the touch function layer 12, the bending shape of the first flexible printed circuit 30 is smooth and the bending radius is great. Therefore, the first supporting layer 40 provided by some embodiments of the present disclosure may ameliorate the problem of a dead bend and a small bending radius that are caused by a sharp bending shape of the first flexible printed circuit 30, thereby reducing the risk the wiring of the first flexible printed circuit 30 being broken.

As shown in FIG. 4, in the case where the second supporting portion 42 extends to the main body portion 32, the bending stiffness of the second supporting portion 42 is less than the bending stiffness of the first supporting portion 41, which may reduce the bending stiffness of the first supporting layer 40 and reduce the bending resistance of the first supporting layer 40, thereby reducing the bending difficulty of the first flexible printed circuit 30 and reducing the elastic restoring force of the first flexible printed circuit 30 after bending. Therefore, the first supporting layer 40 provided in some embodiments of the present disclosure may ameliorate the risk of separation of the first bonding portion 121 and the second bonding portion 31.

In summary, the first supporting layer 40 provided by some embodiments of the present disclosure may alleviate the problems of dead bend and small bending radius that are caused by a sharp bending shape of the first flexible printed circuit 30, thereby reducing the risk of the wiring of the first flexible printed circuit 30 being broken, and reducing the risk of separation of the first bonding portion 121 and the second bonding portion 31.

In some examples, as shown in FIGS. 7 and 8, the second supporting portion 42 includes a plurality of supporting strips 421. For example, the second supporting portion 42 may include two, three, five, or ten supporting strips 421, which is not enumerated one by one in the embodiments of the present disclosure. In the second direction Y, the plurality of supporting strips 421 are arranged at intervals. The second direction Y intersects the first direction X and is parallel to the touch function layer 12. For example, the second direction Y is parallel to the surface of the touch function layer 12 away from of the display function layer 11.

With such an arrangement, the bending stiffness of the second supporting portion 42 may be made less than the bending stiffness of the first supporting portion 41, thereby ameliorating the problems of dead bend and small bending radius that are caused by a sharp bending shape of the first flexible printed circuit 30, and reducing the risk of the wiring of the first flexible printed circuit 30 being broken.

In some examples, as shown in FIG. 8, the second supporting portion 42 includes two supporting strips 421, and the end surfaces of the two supporting strips 421 that are away from each other are flush with the end surface of the first flexible printed circuit 30; that is, the supporting strips 421 are located at the edge of the first flexible printed circuit 30. With such an arrangement, the two supporting strips 421 may support the edge part of the first flexible printed circuit 30 as well as the middle part of the first flexible printed circuit 30.

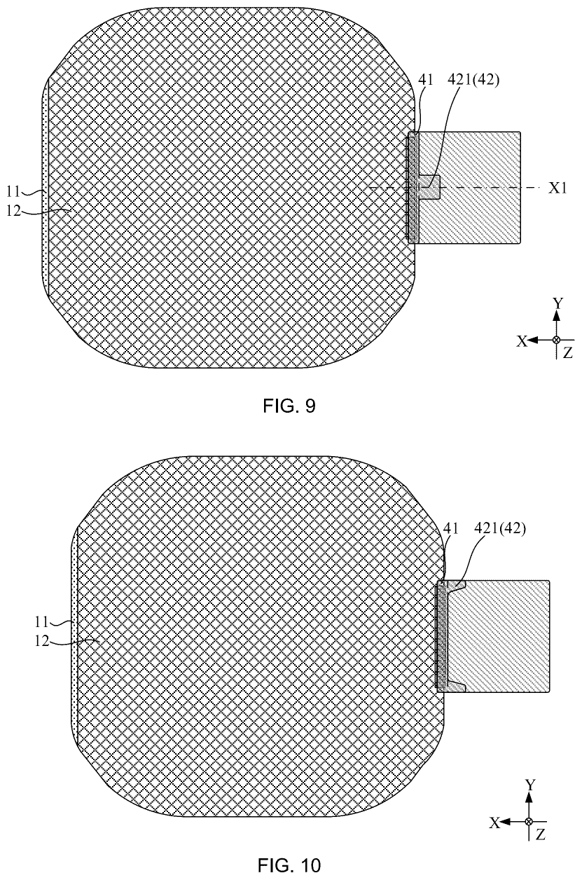

In some other embodiments, as shown in FIG. 9, the second supporting portion 42 includes one supporting strip 421. In the second direction Y, the maximum dimension of the supporting strip 421 is less than the minimum dimension of the first supporting strip 421. By configuring in this manner, the bending stiffness of the second supporting portion 42 may be made less than the bending stiffness of the first supporting portion 41, thereby ameliorating the problems of dead bend and small bending radius that are caused by a sharp bending shape of the first flexible printed circuit 30, and reducing the risk of the wiring of the first flexible printed circuit 30 being broken.

In some embodiments, as shown in FIGS. 8 and 9, the second supporting portion 42 is symmetrical about a first axis X1. The first axis X1 extends in the first direction X and passes through the center of the first flexible printed circuit 30. In this way, during the bending process of the first flexible printed circuit 30, the forces on the parts of the second supporting portion 42 located on both sides of the first axis X1 are balanced, which may reduce the risk of distortion of the bending portion 33.

In some examples, as shown in FIG. 8, the second supporting portion 42 includes two supporting strips 421, and the two supporting strips 421 are located on both sides of the first axis X1 and are symmetrical about the first axis X1.

In some other examples, as shown in FIG. 9, the second supporting portion 42 includes a supporting strip 421, the first axis X1 passes through the supporting strip 421, and parts of the supporting strip 421 located on both sides of the first axis X1 are symmetrical about the first axis X1.

In some embodiments, in the second direction Y, a ratio of the dimension of the second supporting portion 42 to the dimension of the first flexible printed circuit 30 is in a range of 0.1 to 0.2, inclusive. For example, the ratio of the dimension of the second supporting portion 42 to the dimension of the first flexible printed circuit 30 is any one of 0.1, 0.15, or 0.2.

With such a configuration, the ratio of the dimension of the second supporting portion 42 to the dimension of the first flexible printed circuit 30 is greater than 0.1, which may increase the part of the bending portion 33 covered by the second supporting portion 42, so that the second supporting portion 42 may support the bending portion 33 well, so as to alleviate the risk of the wiring in the first flexible printed circuit 30 being broken due to deformation of the bending portion 33.

Furthermore, the ratio of the dimension of the second supporting portion 42 to the dimension of the first flexible printed circuit 30 is less than 0.2, which may reduce the second bending stiffness difference. Thus, near the end surface of the second supporting portion 42 away from the first supporting portion 41, the bending shape of the first flexible printed circuit 30 is smooth, which may reduce the risk of the wiring of the first flexible printed circuit 30 being broken, reduce the bending stiffness of the first supporting layer 40, and reduce the bending resistance of the first supporting layer 40, thereby reducing the bending difficulty of the first flexible printed circuit 30, and reduce the elastic restoring force of the first flexible printed circuit 30 after bending. As a result, the risk of separation between the first bonding portion 121 and the second bonding portion 31 is improved.

In some embodiments, as shown in FIG. 10, in the first direction X, a dimension of the second supporting portion 42 in the second direction Y is gradually reduced. By configuring in this manner, the bending stiffness of the second supporting portion 42 may be reduced in the first direction X, thereby reducing the second bending stiffness difference. Thus, near the end surface of the second supporting portion 42 away from the first supporting portion 41, the bending shape of the first flexible printed circuit 30 is smooth, which may reduce the risk of the wiring of the first flexible printed circuit 30 being broken.

Furthermore, the bending stiffness of the first supporting layer 40 may be further reduced, and the bending resistance of the first supporting layer 40 may be reduced, thereby reducing the bending difficulty of the first flexible printed circuit 30 and reducing the elastic restoring force of the first flexible printed circuit 30 after bending. As a result, the risk of separation of the first bonding portion 121 and the second bonding portion 31 may be reduced.

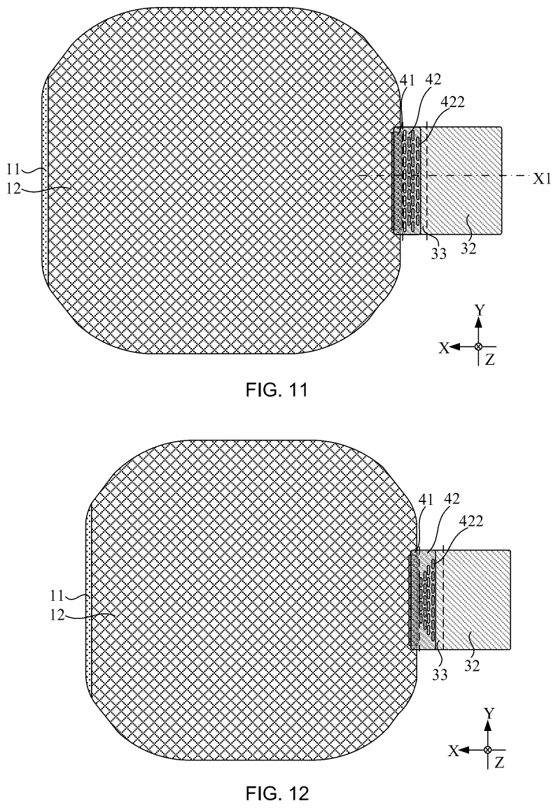

In some embodiments, as shown in FIG. 11, the second supporting portion 42 has a plurality of via holes 422. At least part of orthogonal projections of the plurality of via holes 422 on the first flexible printed circuit 30 is located within the bending portion 33. By configuring in this manner, the bending stiffness of the second supporting portion 42 may be made less than the stiffness of the first supporting portion 41, which may ameliorate the problems of dead bend and small bending radius that are caused by a sharp bending shape of the first flexible printed circuit 30, thereby reducing the risk of the wiring of the first flexible printed circuit 30 being broken.

It will be noted that in a case where an orthographic projection, on the first flexible printed circuit 30, of the end surface of the second supporting portion 42 away from the first supporting portion 41 is located within the bending portion 33, the orthogonal projections of the plurality of via holes 422 on the first flexible printed circuit 30 are located within the bending portion 33. In the case where the second supporting portion 42 extends to the main body portion 32, the orthogonal projections of the plurality of via holes 422 on the first flexible printed circuit 30 are partially located within the bending portion 33 and partially located within the main body portion 3, or the orthogonal projections of the plurality of via holes 422 on the first flexible printed circuit 30 are all located within the bending portion 33.

In some embodiments, as shown in FIG. 11, the plurality of via holes 422 are symmetrical about the first axis X1. With such an arrangement, during the bending process of the first flexible printed circuit 30, the forces on the parts of the second supporting portion 42 located on both sides of the first axis X1 are balanced, which may reduce the risk of distortion of the bending portion 33.

In some embodiments, the shape of the orthogonal projection of the via hole 422 on the first flexible printed circuit 30 includes a long strip, and the via hole 422 extends in the second direction Y.

For example, as shown in FIG. 11, a plurality of via holes 422 are arranged into a plurality of columns of via holes 422 in the second direction Y, each column of via holes 422 includes multiple via holes 422 arranged at intervals in the second direction Y, and the via holes 422 in two adjacent columns are arranged in a staggered manner. It is understandable that the via holes 422 in two adjacent columns may be partially arranged in a staggered manner or completely arranged in a staggered manner.

It will be noted that the orthogonal projection of the via hole 422 on the first flexible printed circuit 30 may be in other shapes, such as a circle, a rectangle, a regular polygon, a rhombus or a cross.

In some embodiments, as shown in FIG. 12, the orthogonal projections of the plurality of via holes 422 on the first flexible printed circuit 30 have a same shape; and in the first direction X, the number of via holes 422 decreases. With such a configuration, the bending stiffness of the second supporting portion 42 may be reduced in the first direction X, thereby reducing the second bending stiffness difference. Near the end surface of the second supporting portion 42 away from the first supporting portion 41, the bending shape of the first flexible printed circuit 30 is smooth which may reduce the risk of the wiring of the first flexible printed circuit 30 being broken.

Furthermore, the bending stiffness of the first supporting layer 40 may be further reduced, and the bending resistance of the first supporting layer 40 may be reduced, thereby reducing the bending difficulty of the first flexible printed circuit 30 and reducing the elastic restoring force of the first flexible printed circuit 30 after bending. As a result, the risk of separation of the first bonding portion 121 and the second bonding portion 31 may be reduced.

In some embodiments, as shown in FIGS. 4 to 12, the first supporting portion 41 and the second supporting portion 42 are of a one-piece structure. By configuring in this manner, the manufacturing process of the first supporting portion 41 and the second supporting portion 42 is simple.

In some embodiments, an elastic modulus of a material of the second supporting portion 42 is less than an elastic modulus of a material of the first supporting portion 41. With such a configuration, the bending stiffness of the second supporting portion 42 may be made less than the stiffness of the first supporting portion 41, which may ameliorate the problems of dead bend and small bending radius that are caused by a sharp bending shape of the first flexible printed circuit 30, thereby reducing the risk of the wiring of the first flexible printed circuit 30 being broken.

For example, the material of the first supporting portion 41 includes polyimide, and the material of the second supporting portion 42 includes at least one of ink, foam, and adhesive.

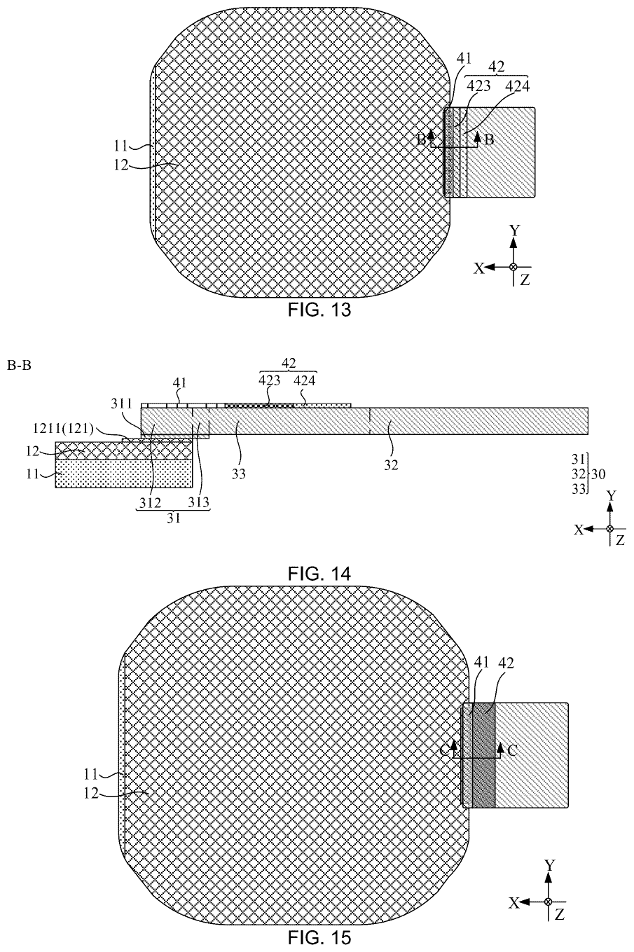

In some embodiments, as shown in FIGS. 13 and 14, the second supporting portion 42 includes a plurality of sub-portions, and in a direction, the elastic modulus of the materials of the plurality of sub-portions decreases. With such configuration, the bending stiffness of the second supporting portion 42 may be reduced in the first direction X, thereby reducing the second bending stiffness difference. Near the end surface of the second supporting portion 42 away from the first supporting portion 41, the bending shape of the first flexible printed circuit 30 is smooth, which may reduce the risk of the wiring of the first flexible printed circuit 30 being broken.

Furthermore, the bending stiffness of the first supporting layer 40 may be further reduced, and the bending resistance of the first supporting layer 40 may be reduced, thereby reducing the bending difficulty of the first flexible printed circuit 30 and reducing the elastic restoring force of the first flexible printed circuit 30 after bending. As a result, the risk of separation of the first bonding portion 121 and the second bonding portion 31 may be reduced.

In some examples, as shown in FIGS. 13 and 14, the second supporting portion 42 includes a first sub-portion 423 and a second sub-portion 424, the first sub-portion 423 is located between the first supporting portion 41 and the second sub-portion 424, and an elastic modulus of a material of the second sub-portion 424 is less than an elastic modulus of a material of the first sub-portion 423.

For example, the material of the first sub-portion 423 includes ink, and the material of the second sub-portion 424 includes foam.

For example, in the first direction X, a ratio of a dimension of the first sub-portion 423 to a dimension of the second sub-portion 424 is 1.

In some embodiments, the material of the first supporting layer 40 includes a host material and a doping material. A doping concentration of the doping material included in the second supporting portion 42 is different from a doping concentration of the doping material included in the first supporting portion 41, so that the bending stiffness of the second supporting portion 42 is less than the stiffness of the first supporting portion 41. As a result, it is possible to ameliorate the problems of dead bend and small bending radius that are caused by a sharp bending shape of the first flexible printed circuit 30, thereby reducing the risk of the wiring of the first flexible printed circuit 30 being broken.

It will be noted that the doping concentration of the doping material included in the second supporting portion 42 may be greater than the doping concentration of the doping material included in the first supporting portion 41, or may be less than the doping concentration of the doping material included in the first supporting portion 41.

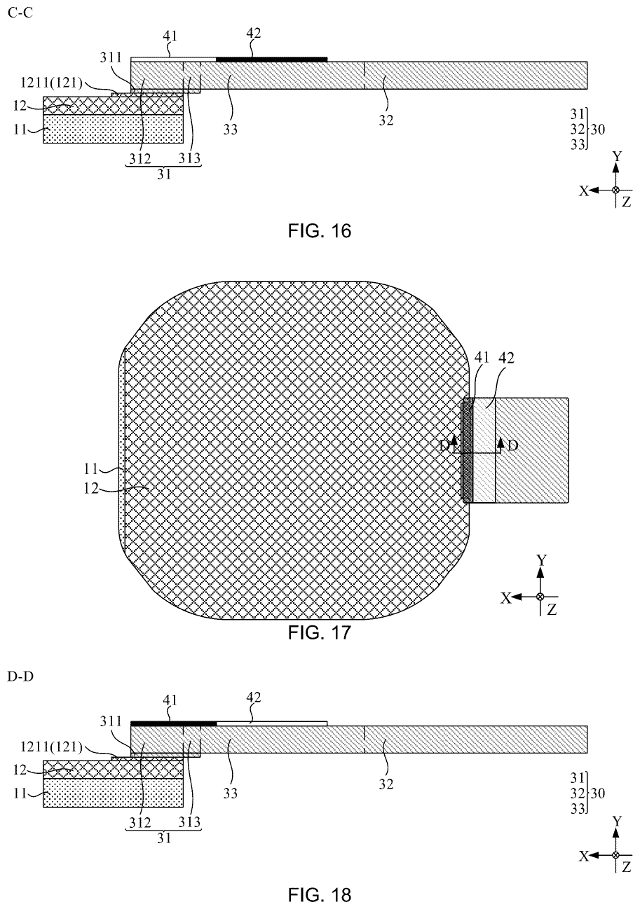

In some examples, as shown in FIGS. 15 and 16, the host material is polyimide, and the doping material is a plasticizer. The plasticizer may reduce the bending stiffness of the plastic. Thus, the doping concentration of the doping material included in the second supporting portion 42 is set to be greater than the doping concentration of the doping material included in the first supporting portion 41, so that the bending stiffness of the second supporting portion 42 is less than the stiffness of the first supporting portion 41.

For example, the doping material includes aliphatic dicarboxylic acid esters, phthalic acid esters, polybenzoic acid esters, benzoic acid esters, polyol esters, chlorinated hydrocarbons, epoxy resins, citrate esters, and the like.

In some other examples, as shown in FIGS. 15 and 16, the host material is polyimide, and the doping material is a toughening agent, which may also reduce the bending stiffness of the plastic. Thus, the doping concentration of the doping material included in the second supporting portion 42 is set to be greater than the doping concentration of the doping material included in the first supporting portion 41, so that the bending stiffness of the second supporting portion 42 is less than the stiffness of the first supporting portion 41.

For example, the doping material includes liquid polysulfide rubber, acrylate-based liquid rubbers, liquid polybutadiene rubber, nitrile rubber, ethylene propylene rubber or styrene butadiene rubber, etc.

In some other examples, as shown in FIGS. 17 and 18, the host material is polyimide, and the doping material is a reinforcing agent, and the reinforcing agent may increase the bending stiffness of the plastic. Thus, the doping concentration of the doping material included in the second supporting portion 42 is less than the doping concentration of the doping material included in the first supporting portion 41, so that the bending stiffness of the second supporting portion 42 is less than the stiffness of the first supporting portion 41.

For example, the doping material includes carbon fiber, glass fiber, or polyester fiber.

In some embodiments, in the first direction X, the doping concentration of the doping material included in the second supporting portion 42 gradually increases or decreases. With such a configuration, the bending stiffness of the second supporting portion 42 may be reduced in the first direction X, thereby reducing the second bending stiffness difference. Near the end surface of the second supporting portion 42 away from the first supporting portion 41, the bending shape of the first flexible printed circuit 30 is smooth, which may reduce the risk of the wiring of the first flexible printed circuit 30 being broken.

Furthermore, the bending stiffness of the first supporting layer 40 may be further reduced, and the bending resistance of the first supporting layer 40 may be reduced, thereby reducing the bending difficulty of the first flexible printed circuit 30 and reducing the elastic restoring force of the first flexible printed circuit 30 after bending. As a result, the risk of separation of the first bonding portion 121 and the second bonding portion 31 may be reduced.

In some examples, as shown in FIGS. 15 and 16, the doping concentration of the doping material included in the second supporting portion 42 is greater than the doping concentration of the doping material included in the first supporting portion 41; and in the first direction X, the doping concentration of the doping material included in the second supporting portion 42 gradually increases. Thus, the bending rigidity of the second supporting portion 42 in the first direction X may be reduced, thereby reducing the second bending rigidity difference. Furthermore, the bending rigidity of the first supporting layer 40 may be further reduced, thereby reducing the bending resistance of the first supporting layer 40.

In some other examples, as shown in FIGS. 17 and 18, the doping concentration of the doping material included in the second supporting portion 42 is less than the doping concentration of the doping material included in the first supporting portion 41; and in the first direction X, the doping concentration of the doping material included in the second supporting portion 42 gradually decreases. Thus, the bending rigidity of the second supporting portion 42 may be reduced in the first direction X, thereby reducing the second bending rigidity difference. Furthermore, the bending rigidity of the first supporting layer 40 may be further reduced, thereby reducing the bending resistance of the first supporting layer 40.

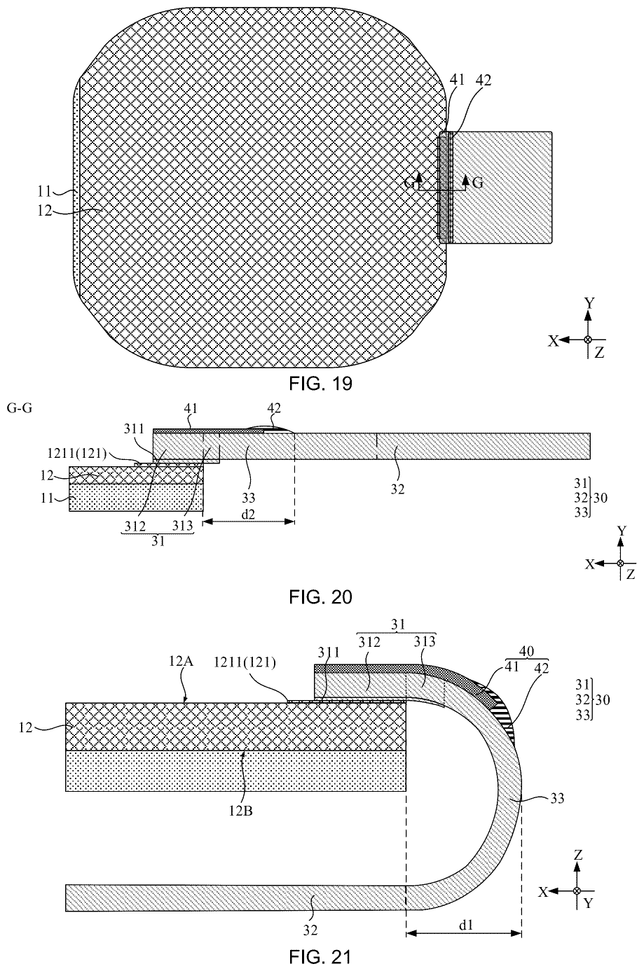

In some embodiments, as shown in FIGS. 19, 20 and 21, in the first direction X, the orthographic projection of the end surface of the second supporting portion 42 away from the first supporting portion 41 on the first flexible printed circuit 30 is located within the bending portion 33. The second supporting portion 42 is partially located on a side of the first supporting portion 41 away from the touch function layer 12, and partially located on a side of the first supporting portion 41 away from the first flexible printed circuit 30. In this way, the contact area between the second supporting portion 42 and the first supporting portion 41 may be increased, thereby improving the reliability of the first supporting portion 41 and the second supporting portion 42.

In some examples, the material of the first supporting portion 41 includes polyimide, and the material of the second supporting portion 42 includes ink. The second supporting portion 42 may be formed by coating an edge of the first supporting portion 41 away from the touch function layer 12 with ink.

In some other examples, the material of the first supporting portion 41 includes polyimide, and the material of the second supporting portion 42 includes an adhesive. The second supporting portion 42 may be formed by attaching an adhesive to an edge of the first supporting portion 41 away from the touch function layer 12. For example, the material of the adhesive includes sealant or UV adhesive.

On the basis of the above embodiments, as shown in FIGS. 19, 20 and 21, in the first direction X, a distance between a surface, away from the first flexible printed circuit 30, of a part of the second supporting portion 42 that is located on the side of the first supporting portion 41 away from the touch function layer 12 and the surface of the first flexible printed circuit 30 proximate to the second supporting portion 42 is reduced. Furthermore, the bending stiffness of the second supporting portion 42 may be reduced in the first direction X, thereby reducing the second bending stiffness difference. Near the end surface of the second supporting portion 42 away from the first supporting portion 41, the bending shape of the first flexible printed circuit 30 is smooth, which may reduce the risk of the wiring of the first flexible printed circuit 30 being broken.

Furthermore, the bending stiffness of the first supporting layer 40 may be further reduced, and the bending resistance of the first supporting layer 40 may be reduced, thereby reducing the bending difficulty of the first flexible printed circuit 30 and reducing the elastic restoring force of the first flexible printed circuit 30 after bending. As a result, the risk of separation of the first bonding portion 121 and the second bonding portion 31 may be reduced.

In some embodiments, as shown in FIG. 21, the maximum distance between the bending portion 33 and the touch function layer 12 is d1. As shown in FIG. 20, in the first direction X, the distance between the end surface of the second supporting portion 42 away from the first supporting portion 41 and the end surface of the touch function layer 12 proximate to the bending portion 33 is d2, and d1−d2=0.1 mm.

With such configuration, in the bent state, the maximum distance between the bending portion 33 and the second supporting portion 42 may be less than the maximum distance between the bending portion 33 and the touch function layer 12. That is, compared to the end of the second supporting portion 42 away from the touch function layer 12, the end of the bending portion 33 away from the touch function layer 12 is farther away from the touch function layer 12. The frame of the display device 1000 corresponding to the bending portion 33 may be designed to be narrow, which is more conducive to the narrow bezel design of the display device 1000.

In some embodiments, the bending radius of the first flexible printed circuit 30 is in a range of 0.3 mm to 0.5 mm, inclusive. For example, the bending radius of the bending portion 33 may be 0.3 mm, 0.36 mm, 0.38 mm, 0.4 mm, 0.42 mm, 0.46 or 0.5 mm.

It is understandable that the less the bending radius of the bending portion 33 is, the narrower the frame of the display device 1000 corresponding to the bending portion 33 (the lower frame in FIG. 1) may be designed, which is more conducive to the narrow bezel design of the display device 1000. For example, the bending radius of the bending portion 33 may be in a range of 0.3 mm to 0.4 mm; for example, the bending radius of the bending portion 33 may be 0.3 mm, 0.32 mm, 0.36 or 0.4, so that the frame of the display device 1000 corresponding to the bending portion 33 (the lower frame in FIG. 1) may be made narrow.

In some embodiments, as shown in FIG. 2, the display module 100 further includes a second flexible printed circuit 50, and the second flexible printed circuit 50 is connected to the display function layer 11 and the main flexible printed circuit 1. In this way, the main flexible printed circuit 1 may provide signals for the display function layer 11 through the second flexible printed circuit 50 to realize the display function. In this case, the second flexible printed circuit 50 may be referred to as a chip on flex (COF).

In some embodiments, the display module 100 further includes a cover plate 60, a first adhesive layer 70, a circular polarizer 80 and a buffer layer 90. The circular polarizer 80 is disposed on the display surface of the display panel 10, and is configured to reduce reflection of ambient light by the display panel 10.

The cover plate 60 is disposed on a side of the circular polarizer 80 away from the display panel 10, and is configured to protect the display panel 10 and reduce the risk of the display panel 10 being scratched.

The first adhesive layer 70 is located between the cover plate 60 and the circular polarizer 80, and the first adhesive layer 70 bonds the cover plate 60 to the circular polarizer 80.

For example, the material of the first adhesive layer 70 may include optically clear adhesive (OCA), pressure sensitive adhesive (PSA) or other adhesive materials with high light transmittance. For example, the material of the first adhesive layer 70 includes optically clear adhesive.

The buffer layer 90 is located on the non-display surface 10B of the display panel 10. The buffer layer 90 may play a good buffering role, which is helpful to reduce the risk of damage to the display panel 10.

For example, the material of the buffer layer 90 includes a super clean foam (SCF) composite film.

For example, the super clean foam composite film includes an adhesive layer, a buffer layer, and a heat dissipation layer that are sequentially stacked in a direction away from the display panel.

The adhesive layer is used to bond the buffer layer and the heat dissipation layer to a side of the display panel, and the adhesive layer may be flexible, which is beneficial to the flexible design of the display module 100. For example, a material of the adhesive layer includes a hydrophobic material.

The buffer layer may not only play a buffering function for the stress acting on the display panel 10, but also be used for light shielding, thereby improving the display effect of the display panel 10. For example, the material of the buffer layer includes foam, and the color of the buffer layer is dark (for example, the material of the buffer layer is black).

The heat dissipation layer may be used to dissipate the heat generated by the display panel 10 when operation, so as to reduce the risk of the display panel 10 being burned due to the high heat of the display panel 10. For example, the material of the heat dissipation layer includes a metal material.

In the description of the specification, specific features, structures, materials or characteristics may be combined in any suitable manner in any one or more embodiments or examples.

The foregoing descriptions are merely specific implementations of the present disclosure, but the protection scope of the present disclosure is not limited thereto, any variations or substitutions that those skilled in the art could conceive of within the technical scope of the present disclosure shall fall within the protection scope of the present disclosure. Therefore, the protection scope of the present disclosure should be determined by the protection scope of the claims.

1. A display module, comprising:
a touch function layer having a touch surface and a non-touch surface that are oppositely disposed, wherein the touch function layer includes a first bonding portion, and the first bonding portion is located on the non-touch surface;
a first flexible printed circuit including a second bonding portion, a main body portion, and a bending portion disposed between the second bonding portion and the main body portion, wherein the second bonding portion is bonded to the first bonding portion, and the bending portion is bent toward the non-touch surface, so that the main body portion is bent onto the non-touch surface;
a first supporting layer disposed on a side of the first flexible printed circuit away from the touch function layer, wherein the first supporting layer includes a first supporting portion and a second supporting portion that are connected to each other, the first supporting portion covers the second bonding portion and extends to the bending portion; in a first direction, at least part of the second supporting portion is located on a side of the first supporting portion away from the touch function layer, and a bending stiffness of the second supporting portion is less than a bending stiffness of the first supporting portion.

2. The display module according to claim 1, wherein the second supporting portion includes a plurality of supporting strips, the plurality of supporting strips are arranged at intervals in a second direction; the second direction intersects the first direction and is parallel to the touch function layer.

3. The display module according to claim 2, wherein the second supporting portion includes two supporting strips, and end surfaces of the two supporting strips that are away from each other are flush with an end surface of the first flexible printed circuit.

4. The display module according to claim 1, wherein the second supporting portion includes one supporting strip; in a second direction, a maximum dimension of the supporting bar is less than a minimum dimension of the first supporting portion; the second direction intersects the first direction and is parallel to the touch function layer.

5. The display module according to any one of claims 2 to 4, wherein the second supporting portion is symmetrical about a first axis; the first axis extends in the first direction and passes through a center of the first flexible printed circuit.

6. The display module according to any one of claims 2 to 5, wherein in the second direction, a ratio of a dimension of the second supporting portion to a dimension of the first flexible printed circuit is in a range of 0.1 to 0.2, inclusive.

7. The display module according to any one of claims 1 to 6, wherein the second supporting portion has a plurality of via holes; at least part of orthogonal projections of the plurality of via holes on the first flexible printed circuit is located within the bending portion.

8. The display module according to claim 7, wherein the plurality of via holes are symmetrical about a first axis; the first axis extends in the first direction and passes through a center of the first flexible printed circuit.

9. The display module according to claim 8, wherein a shape of an orthogonal projection of a via hole on the first flexible printed circuit includes a long strip, and the via hole extends in a second direction; the second direction intersects the first direction and is parallel to the touch function layer.

10. The display module according to any one of claims 2 to 9, wherein the first supporting portion and the second supporting portion are of a one-piece structure.

11. The display module according to any one of claims 1 to 9, wherein an elastic modulus of a material of the second supporting portion is less than an elastic modulus of a material of the first supporting portion.

12. The display module according to claim 11, wherein in the first direction, the second supporting portion includes a first sub-portion and a second sub-portion, the first sub-portion is located between the first supporting portion and the second sub-portion, and an elastic modulus of a material of the second sub-portion is less than an elastic modulus of a material of the material of the first sub-portion.

13. The display module according to claim 12, wherein the material of the first sub-portion includes ink, and the material of the second sub-portion includes foam.

14. The display module according to any one of claims 11 to 13, wherein the material of the first supporting portion includes polyimide, and the material of the second supporting portion includes at least one of ink, foam, and adhesive.

15. The display module according to any one of claims 1 to 9, wherein a material of the first supporting portion includes a host material and a doping material;
a doping concentration of the doping material included in the second supporting portion is different from a doping concentration of the doping material included in the first supporting portion.

16. The display module according to claim 15, wherein in the first direction, the doping concentration of the doping material included in the second supporting portion gradually increases or gradually decreases.

17. The display module according to any one of claims 1 to 16, wherein in the first direction, an orthographic projection of an end surface of the second supporting portion away from the first supporting portion on the first flexible printed circuit is located within the bending portion, and the second supporting portion is partially located on a side of the first supporting portion away from the touch function layer, and partially located on a side of the first supporting portion away from the first flexible printed circuit;
in the first direction, a distance between a surface, away from the first flexible printed circuit, of a part of the second supporting portion that is located on the side of the first supporting portion away from the touch function layer and a surface of the first flexible printed circuit 30 proximate to the second supporting portion is reduced.

18. The display module according to claim 17, wherein in the first direction, a maximum distance between the bending portion and the touch function layer is d1, and a distance between an end surface of the second supporting portion away from the first supporting portion and an end surface of the touch function layer proximate to the bending portion is d2, wherein d1−d2=0.1 mm.

19. The display module according to any one of claims 1 to 18, wherein a bending radius of the first flexible printed circuit is in a range of 0.3 mm to 0.5 mm, inclusive.

20. A display device, comprising the display module according to any one of claims 1 to 19.
